(19) United States
(12) Patent Application Publication
(10) Pub. No.: US 2008/0180152 A1
(43) Pub. Date: Jul. 31, 2008

(54) Method of Phase Noise Reduction in a Soi Type Master-Slave Circuit

(76) Inventor: Vincent Desortiaux, Bois-Colombes (FR)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 11/547,548

(22) PCT Filed: Mar. 11, 2005
(86) PCT No.: PCT/IB2005/000902

§ 371 Date: Nov. 15, 2007

(30) Foreign Application Priority Data
Mar. 29, 2004 (FR) 04/03202

(51) Int. Cl. H03K 3/356; G06F 17/50

(52) U.S. Cl. 327/203; 716/2

(57) ABSTRACT

The invention provides a design method for reducing phase noise of an electronic circuit comprising a master section and a slave section, said sections including SOI type transistors, characterised in that, first, the floating body transistors which are involved in the degradation of said phase noise are located, then their floating body is set to a potential by means of an appropriate connection, in order to locally reduce their contribution to the overall phase noise of said circuit. It also provides a reduced phase noise master-slave circuit. This circuit includes floating body SOI type transistors, characterised in that the potential of said floating body of the transistors that (60, 61) contribute to said phase noise is set by means of an appropriate connection (64, 65).

This invention relates to the design of SOI (Silicon-On-Insulator) technology circuits.

More specifically, this invention relates to a design method for reducing phase noise of an electronic circuit that includes a master section and a slave section. Said sections include SOI-type transistors.

Methods of this type are already known, and particularly, with the use of such SOI technology as compared with bulk silicon technology, the performance of master-slave circuits, and more generally, digital or analog-circuits may be improved significantly.

Indeed, it is known that with SOI technology, components with excellent performance levels may be provided to the circuit designer. For example, by having an oxide buried in the SOI transistor, fast and low-consumption transistors, passive components such as resistors or capacitors with a good quality factor, and means for reducing insulation and coupling, are made available to the designer.

However, such technology includes specific features, in particular at the transistor level, which should be mastered when designing a circuit.

A known example of such a feature consists in excess noise present in the SOI transistor at low frequencies, this noise notably generating phase noise in the circuit, a disadvantage in terms of performance.

Before explaining certain origins of this noise in SOI technology, the notion of noise will briefly and generally be recalled here, in connection with phase noise.

Generally, a signal propagates through a circuit within a certain period of time, currently referred to under the term of delay.

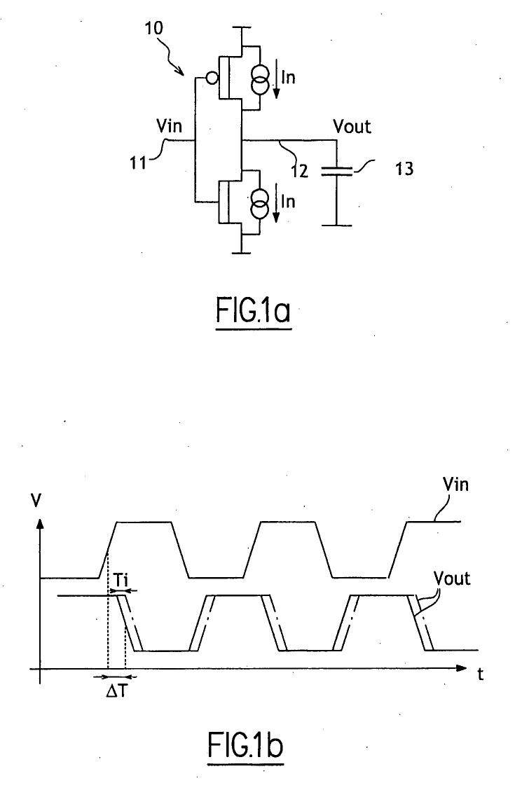

A delay may be illustrated as shown in FIG. 1b, wherein a Vin input signal and a Vout output signal of an inverter 10 (see FIG. 1A) are shown schematically.

The aforementioned delay is identified by the time interval ΔT between both Vin and Vout signals.

Furthermore, two current sources designated In and shown in FIG. 1A respectively model a noise source in each of the NMOS and PMOS transistors of the inverter.

These currents representative of noise are added to the conduction current of the transistors in the output branch 12 and the whole contributes, depending on the voltage Vin level on input 11, to the charging or discharging of capacitor 13.

It is known that the times for charging or discharging this capacitor are related to the current flowing in the output 12 by the following relationship:

$$Δ T = \frac{C}{I} Δ V \qquad ( 1 )$$

where ΔT is the charging or discharging time, C is the value of capacitance 13, ΔV is a voltage difference between the beginning and the end of the charging or discharging, and I is the output current.

Note that from this equation the transistor noise directly affects the ΔT time since current I includes the Iin noise currents.

Now, this ΔT time corresponds specifically to the propagation delay of a signal passing from the input to the output of the inverter.

Therefore, transistor noise contributes to some extent to this time delay inconvenience.

And the stronger the intrinsic noise of the transistors, which corresponds to a high In value, the more significant and thereby detrimental, this contribution becomes in terms of performance.

A very important aspect of this phenomenon is also that there is increasing uncertainty regarding the evaluation of the ΔT propagation delay.

Indeed, said noise is random noise and it provides the ΔT delay with this same random feature.

Of course, the larger this noise level, the more the possible but unpredictable change in ΔT increases, which actually expresses the aforementioned notion of uncertainty with regards to the value of ΔT.

Such an uncertainty is currently called time jitter Tj.

It therefore corresponds to the difference between the maximum propagation delay and the minimum propagation delay associated with a circuit and the signals that are applied thereto.

Similarly, a phase error Φj may be defined by normalising said time jitters Tj relatively to a period of the relevant signal, with the following relationship:

$${Φ}_{j} = \frac{2 Π {T}_{j}}{T} \qquad ( 2 )$$

Φj being the phase error and T the signal period.

The notion of phase noise L (Fo) which itself represents a noise density in a one Hz frequency band at an Fo frequency offset, relatively to the total power of a signal, may now be introduced.

This noise phase is linked to the phase error Dj through the following relationship:

Φⱼ²=∫L(F)dF

Now, as regards SOI transistors, compared with bulk silicon transistors, this phase noise is substantially greater at a low frequency offset: therefore, this may be referred to as an excess of noise and of low frequency phase noise of an SOI transistor.

Such an excess is notably derived from the electrical insulation of a floating area located under the SOI transistor's gate, currently called floating body.

This body actually generates additional noise called excess phase noise that is particularly troublesome, especially in analog applications in which low frequency noise essentially determines the performance of the electronic function.

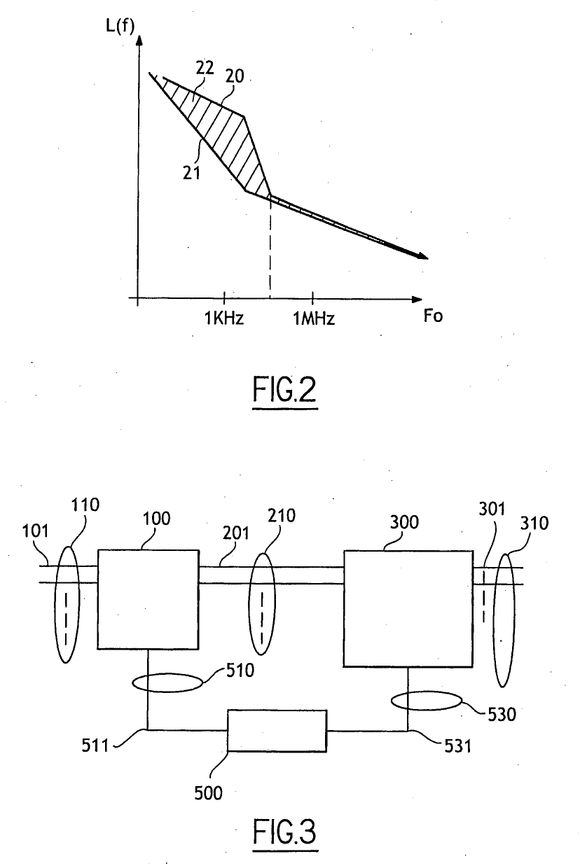

An example is given in FIG. 2, where the phase noise is illustrated as obtained at the output of a series of inverters made with SOI technology 20 and bulk body technology 21.

A significant low frequency phase noise difference can be observed in particular, in the hatched area 22 which represents a frequency band approximately centred around 1 kHz.

Here, it is understood that the shape of the curves, as well as the values represented in the Fig. are only an illustration of the above example.

Thus, SOI technology largely improves the performances of electronic circuits, but because of the floating body, the design of certain circuits must be especially adapted and carefully performed.

This invention is directed to helping the designer in this approach by providing design methods for circuits specific to SOI technology.

More particularly, an object of this invention is to provide a simple method and a reliable one in terms of results which in particular, may get rid of the inconvenience related to said noise excess of a partly depleted SOI transistor.

For this purpose, this invention provides a design method for a reduced phase noise electronic circuit comprising a master section and a slave section, said sections comprising a plurality of SOI type floating body transistors, characterised in that the floating body transistor(s) which contribute to deteriorating phase noise are located first, and then their floating body is set to a potential by means of an appropriate connection in order to locally decrease their contribution to the overall phase noise of said circuit.

Some preferred, although not exclusive, aspects of this method are the following:
Said localization of the transistors consists in finding those that, associated with the slave section, pass from a conducting on-state to a blocking off-state and vice versa, when a data signal from an input is transferred to an output of said slave section.
Only the transistors which are moreover located along the electric path that a data element follows between an input and an output of this slave section, are selected.
Certain floating bodies are connected to an electrical source of the type selected from a voltage source and a current source.
Certain floating bodies are connected to a polarisation circuit.
The floating bodies are each connected to a circuit node.
The node is a transistor gate, drain or source.
Each transistor's floating body is connected to the gate, drain, or source thereof.
A connection is implemented by a floating body contact.

Another object of this invention is to propose a master-slave electronic circuit with reduced phase noise, said circuit comprising SoI type Floating body transistors, characterised in that the potential of the floating body of certain transistors identified as contributing to the phase noise is set by means of an appropriate connection.

Certain preferred, although non-limiting aspects of this circuit are the following:
The transistors identified as contributing to said noise are in the slave section.
The transistors contributing to said noise are those that pass from a conducting on-state to a blocked off-state and vice versa, when a data signal from an input is transferred to an output of said slave section.
Moreover, the transistors are located along the electric path that a data element follows between an input and an output of the slave section.
The floating body of certain of said transistors that change state is connected to an electrical source of the type selected from a voltage source and a current source.
The floating body of certain of these transistors is connected to a circuit node.
The node is a transistor gate, drain or source.
Each transistor's floating body is connected to the gate, drain or source thereof.
A floating body connection contains a floating body contact.
Each of these sections is a latch circuit so that this electronic circuit is a bistable trigger circuit.

Another object of this invention is to provide a simulation file containing a set of structured data representative of a reduced phase noise circuit with master and slave sections, said circuit includes SOI type floating body transistors, characterised in that certain of these data are data for connecting the floating body of certain transistors previously identified as contributing to the phase noise, to a node with the appropriate potential.

Another object of this invention is to provide a simulation file for manufacturing an electronic circuit with reduced phase noise, said circuit comprising a master section and a slave section, comprising both a plurality of floating body SOI type transistors, said simulation file containing a set of structured data representative of said circuit, characterised in that some of these data represent a connection between the floating body of certain transistors, identified before-hand as contributing to the phase noise, and a nod with an appropriate bias.

Other aspects, objects and advantages of this invention will become more apparent upon reading the following detailed description of a preferred embodiment of this invention, given as a non-limiting example and made with reference to the attached drawings, in which:

FIG. 1a schematically represents a CMOS SOI type inverter.

FIG. 1b illustrates the time signals associated with a simulation of said inverter of the previous figure.

FIG. 2 illustrates a phase noise obtained at the output of a series of SOI type CMOS inverters.

FIG. 3 illustrates a typical synchronous master-slave circuit.

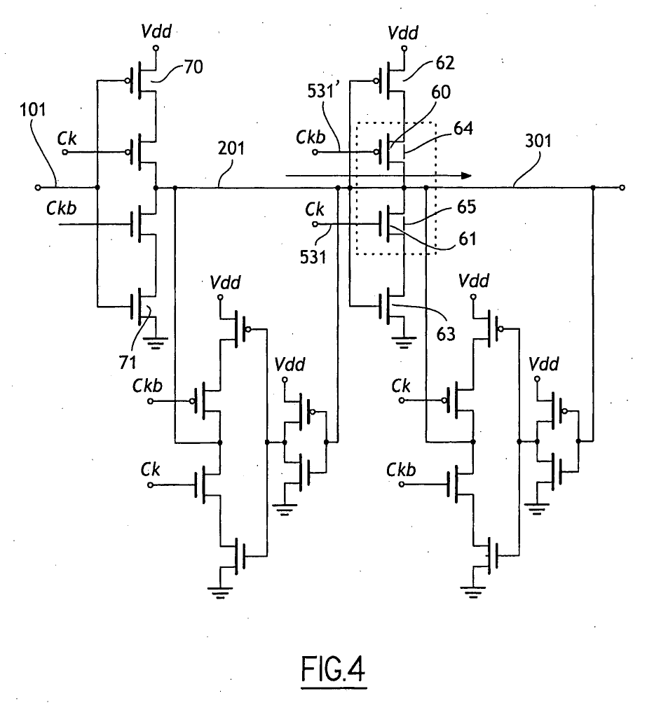

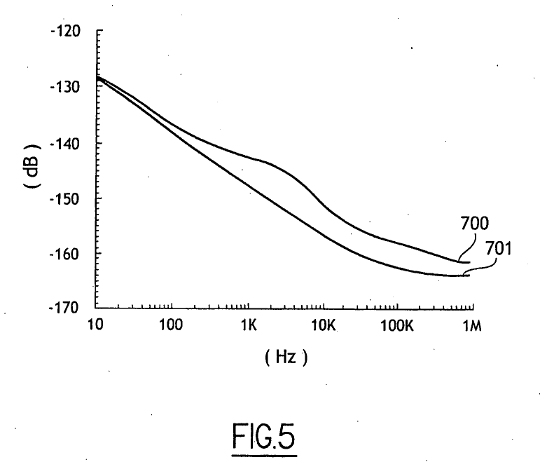

FIG. 4 shows an exemplary embodiment according to the invention of an SOI type bistable trigger circuit.

FIG. 5 illustrates a comparison of the phase noise frequency response between an optimised version according to the invention of said SOI trigger circuit and a second, non-optimised version.

By referring now to the drawings and, more particularly, to FIG. 3, a circuit with a master section 100 and a slave section 300 is illustrated.

Both of these circuits include at least one input and at least one output.

More specifically, in FIG. 3, the signal networks 110, 210, 310, 510, and 530 are drawn to illustrate the possible presence of several inputs or outputs.

However, for the sake of clarity, simple circuits which do not include input and output networks will be discussed in the following text.

The first circuit 100 therefore comprises an input 101 at which a binary datum D arrives.

Once it is processed by the first circuit, this datum is transferred to output 201 in response to a clock signal 511 from a clock circuit 500.

Said output also corresponds to the input of slave circuit 300 which, upon completion of this processing operation, receives said datum D.

In turn, and under the control of a control signal 531, circuit 300 processes the datum D and completes the operation by forwarding it to its output 301.

With a circuit 500, it is possible to generate said command signals of circuits 100 and 300, even more generally, of circuits which make up a larger system.

Therefore, a polar inversion of clock signals 511 and 531 is frequently put into practice to offset the respective processing operations of a single datum by a half clock period, performed by the master section and then by the slave section.

In this case, circuit 500 may comprise a simple inverter between clock paths 511 and 531.

When such master-slave circuits are embodied in SOI technology with transistors including a floating body, deterioration of performance is observed in terms of jitter, as compared to an embodiment in bulk technology.

The applicant has observed that during the design of such an SOI technology circuit, only a few transistors including a floating body contribute to this degradation.

Indeed, they correspond to those transistors which, associated with the operation of the slave section, pass from a conducting on-state to a blocked off-state, and vice versa, when a data signal from an input 201 is transferred to an output 301 of said slave section.

Moreover, these transistors are frequently located on the electric path followed by a datum between input 201 and output 301.

The applicant has thus noted that, generally, the location of these transistors meets the following cumulative features:
They are located on the propagation path of a datum.
They are located between output 201 of the master section and 301 of the slave section.
They are located between the clock signal 531 of the slave section and its output 301.

According to the invention, in order to get rid of such an inconvenience and thereby enhance the performances of the master-slave circuit in terms of jitter, the potentials of the floating bodies of these transistors are set to a desired value.

For this purpose, during the design and the simulation phase of said circuit, an electrical source may simply be connected to the floating bodies of said transistors.

However, within the framework of a physical embodiment of said circuit (layout circuit), it is preferable to establish a connection to an internal node of the circuit each time.

It will be noted that it is not at all mandatory that said node be internal to the slave section. The aim here is to establish an optimum connection.

In some cases, such a connection must guarantee stable polarisation voltage under all circumstances; a known polarisation circuit may be used for this purpose.

In other cases, the connection must be dynamic, i.e. the polarisation voltage must vary according to conditions known by the designer.

An example of such a connection consists in connecting the floating body of the transistor to the node of one of the terminals of this same transistor, selected from its gate, source and drain, whilst being aware that on this terminal, the voltage varies over time and thereby induces certain related advantages.

For example, one advantage is that such a connection is relatively simple to implement during the making of physical masks for producing the circuit.

Moreover, carefully selecting the terminal in some cases, may further improve operation of the transistor.

Of course, the selected terminal may also be used to provide a stable polarisation voltage.

Connecting the floating body of the transistor to the terminal in this case, amounts to establishing a static type connection, as in one of the previous options.

An embodiment of the method according to the invention will now be described.

FIG. 4 illustrates a circuit known per se and typically aimed by the method according to this invention.

Known as a bistable trigger circuit of type D, or D flip-flop, it comprises two latch circuits, one master and the other slave.

The very well known operation of this type of circuit is basically recalled here.

A first phase occurs, called preload, where clock signals 531 and 531′ are low and high, respectively.

The first latch circuit (master circuit) measures the voltage level of input 101 of a new datum D, by using transistors 70 and 71, whilst the previous datum is stored in the second latch circuit and transferred to the output 301.

Next, during a second phase, where the clock levels are inverted, the first latch circuit transfers said datum D over to the output 201, whilst the second latch circuit measures this datum at its input, by using transistors 62 and 63.

This cycle comprised of the two phases described, is repeated as many times as desired and, for example, during the next cycle, signals 531 and 531′ will be such that transistors 60 and 61, respectively, will allow said datum D to be transferred to output 301 of the said trigger circuit.

A transformation that is commonly applied for implementing this type of SOI technology circuit, starting from a bulk body technology, consists in replacing each MOS transistor with its SOI equivalent.

The mentioned inconveniences in terms of phase noise, and therefore jitter, will arise.

According to the invention, the transistors which meet said criteria as described above, are located.

It is noted here that only transistors 60 and 61 are affected.

Indeed, during the first phase, the clocks are at such voltage levels that transistors 60 and 61 are blocked (the voltage differential between the gate and source is substantially zero.)

During the second phase, the clock signals having switched, these two transistors are in the conducting on-state.

Accordingly, during the transfer of the datum D from input 201 to output 301, both of these transistors meet said criterion as defined earlier.

Therefore, their respective floating body is connected to a voltage source.

As an example, a connection to the gate enables the floating bodies 64 and 65 to be connected to the respective clock signals.

In this case, the floating body is no longer floating, but its voltage varies from one phase to another.

Nonetheless, it remains constant during an entire phase.

Therefore, the transistors have a dynamic configuration, their performance varying from one phase to another.

As regards to the other transistors associated with the slave circuit, an analysis shows that they do not meet said criterion, and that no step for connecting their body is required, considering the problem to be solved.

FIG. 5 illustrates the simulated performance in terms of phase noise with the circuit according to the invention and the performance obtained if no optimisation is implemented.

The performance associated with the circuit of the invention is identified by curve 701.

It is seen that the excess of low frequency phase noise, clearly evident in curve 700, in particular in the frequency range between about 1 kHz and 10 kHz, is considerably reduced in curve 701.

The proposed method is therefore very effective, although simply implemented.

Although a specific embodiment has been described, it is understood by one skilled in the art that several other alternatives are possible, without departing from the general scope of this invention.

In particular, this invention is in no way limited by the number of slave circuits which may be associated with a master circuit.

Moreover, as illustrated in FIG. 3, the principle of this invention equally applies when the circuits have networks of input and/or output signals.

Lastly, it is understood that the above description is based on the principle that, in particular, the clock signals routed to the latch circuits and more specifically to the slave circuit, are jitter-free to some extent.

This notably supposes that circuit 500 in FIG. 3 is also able to provide such signals.

As an example, if the complementarity of clock signals 531 and 531′ is achieved by an inverter, the design of the latter is then carefully examined in order to guarantee the lowest possible jitter (or phase noise) (a floating body connection may also be considered in this case.)

1-21. (canceled)

22. A method for designing an electronic circuit with reduced noise phase comprising a master section and a slave section, said sections comprising a plurality of floating body SOI type transistors, comprising:
selecting the or each floating body transistor which contributes to phase noise degradation,
setting the floating body of said or each said located transistor to a potential by means of a connection, in order to locally reduce its contribution to the overall phase noise of said circuit.

23. A method according to claim 22, wherein said selection step comprising searching for the or each transistor associated with the slave section and which switches from a conducting or on-state to a blocked or off-state, or vice versa, during the transfer of a data signal from an input to an output of said slave section.

24. A method according to claim 23, wherein that selection step selects only the or each transistor which is located on the electric path followed by said data signal.

25. A method according to claim 22, wherein the floating body of at least one switching transistor is connected to an electrical source of the type selected from a voltage source and a current source.

26. A method according to claim 22, wherein the floating body of at least one transistor is connected to a polarization circuit.

27. A method according to claim 22, wherein the floating body of at least one transistor is connected to a node of the circuit.

28. A method according to claim 27, wherein said node is a gate, a drain or a source of a transistor.

29. A method according to claim 28, wherein each floating body of a transistor is connected to the gate, the drain, or the source thereof.

30. A method according to claim 22, wherein said connection comprises a floating body contact.

31. An electronic circuit comprising a master section and slave section, said circuit comprising a plurality of floating body SOI type transistors, wherein the potential of the floating body of at least one transistor identified as contributing to phase noise is set by means of a connection, whereby the phase noise of the circuit is reduced.

32. A circuit according to claim 31, wherein said at least one transistor is located in the slave section.

33. A circuit according to claim 32, wherein said at least one transistor is a transistor which switches from a conducting or on-state to a blocked or off-state, or vice versa, during the transfer of a data signal from an input to an output of said slave section.

34. A circuit according to claim 33, wherein said at least one transistor is located on the electrical path of said data signal.

35. A circuit according to claim 34, wherein the floating body of at least one switching transistor is connected to an electrical source of the type selected from a voltage source and a current source.

36. A circuit according to claim 33, wherein the floating body of at least one transistor is connected to a node of the circuit.

37. A circuit according to claim 36, wherein the node is a gate, a drain or a source of a transistor.

38. A circuit according to claim 37, wherein the floating body of at least one transistor is connected to the gate, the drain or the source thereof.

39. A circuit according to claim 31, wherein said connection comprises a floating body contact.

40. A circuit according claim 31, wherein each of said master and slave sections is a latch circuit, said circuit being a bistable trigger circuit.

41. A simulation file containing a set of structured data representative of a master section and slave section circuit with low phase noise, said circuit comprising floating body SOI type transistors, wherein said data include data for connecting the floating body of certain transistors previously identified as contributing to the phase noise to a node with an appropriate potential.

42. A simulation file for manufacturing an electronic circuit with reduced phase noise, said circuit comprising a master section and a slave section each comprising a plurality of floating body SOI type transistors, said simulation file containing a set of structured data representative of said circuit, wherein said data include data representative of a connection between the floating body of certain transistors, previously identified as contributing to the phase noise, and a node with an appropriate bias.
